(19) United States
(12) Patent Application Publication
(10) Pub. No.: US 2026/0230095 A1
(43) Pub. Date: Aug. 6, 2026

(54) FREQUENCY CONVERSION CIRCUIT, ANTENNA SYSTEM AND ELECTRONIC DEVICE

(71) Applicants: Beijing BOE Technology Development Co., Ltd., Beijing (CN); BOE Technology Group Co., Ltd., Beijing (CN)

(72) Inventors: Junwei GUO, Beijing (CN); Xichao FAN, Beijing (CN); Wei LI, Beijing (CN); Dongdong ZHANG, Beijing (CN)

(21) Appl. No.: 19/152,022

(22) PCT Filed: Jun. 12, 2024
(86) PCT No.: PCT/CN2024/098540

§ 371 Date: Jul. 30, 2025

(30) Foreign Application Priority Data
Jul. 10, 2023 (CN) 202310841113.3

(51) Int. Cl. H04B 1/00; H03D 7/16; H03H 7/46

(52) U.S. Cl. CPC H04B 1/0096; H03D 7/16; H03H 7/463

(57) ABSTRACT

A frequency conversion circuit has an input, first and second outputs, and includes a frequency selector subcircuit, a combiner subcircuit, and a mixer subcircuit. The frequency selector subcircuit is configured to select, according to frequencies, first to third frequency band signals, and a local oscillator signal from radio frequency signals input at the input. The third frequency band signal has a frequency between frequencies of the first and second frequency band signals. The combiner subcircuit is configured to combine the first and second frequency band signals, and output, at the first output, a first radio frequency signal including at least a radio frequency signal in a specific frequency band. The mixer subcircuit is configured to mix the third frequency band signal with the local oscillator signal, and output a second radio frequency signal, which is the radio frequency signal of in the specific frequency band, through the second output.

### CROSS-REFERENCE TO RELATED APPLICATION

This is a National Phase Application filed under 35 U.S.C. 371 as a national stage of PCT/CN2024/098540, filed on Jun. 12, 2024, an application claiming the benefit of Chinese Application No. 202310841113.3 filed on Jul. 10, 2023, the content of each of which is hereby incorporated by reference in its entirety.

### TECHNICAL FIELD

The present disclosure belongs to the technical field of communications, and specifically relates to a frequency conversion circuit, an antenna system and an electronic device.

### BACKGROUND

In the existing indoor distribution system, the 5th generation mobile communication technology (5G) is more widely applied in order to realize wireless communication of high speed and high reliability. In a 5G signal distribution system, a multiple input multiple output (MIMO) antenna is often needed due to a large amount of user data. However, the existing indoor distribution systems are basically upgraded from 4G indoor distribution systems, which cannot support the use of 5G MIMO antennas, while comprehensive transformation requires large equipment and high construction cost. Therefore, there is a demand for a more efficient and more reliable signal transmission scheme to solve these problems.

### SUMMARY

To solve at least one of the technical problems in the existing art, the present disclosure provides a frequency conversion circuit, an antenna system and an electronic device.

In a first aspect, an embodiment of the present disclosure provides a frequency conversion circuit having an input, a first output, and a second output; wherein the frequency conversion circuit includes a frequency selector subcircuit, a combiner subcircuit, and a mixer subcircuit; wherein
the frequency selector subcircuit is configured to select, according to frequencies, a first frequency band signal, a second frequency band signal, a third frequency band signal, and a local oscillator signal from radio frequency signals input at the input; and the third frequency band signal has a frequency between frequencies of the first frequency band signal and the second frequency band signal;
the combiner subcircuit is configured to combine the first frequency band signal and the second frequency band signal, and output, at the first output, a first radio frequency signal including at least a radio frequency signal in a specific frequency band; and
the mixer subcircuit is configured to mix the third frequency band signal with the local oscillator signal, and output a second radio frequency signal through the second output, wherein the second radio frequency signal is the radio frequency signal in the specific frequency band.

The radio frequency signal in the specific frequency band is a 5G radio frequency signal.

The frequency selector subcircuit includes a first duplexer, a second duplexer, a matching circuit, and a first dielectric filter;
the first duplexer has a first radio frequency channel and a second radio frequency channel, the first radio frequency channel is configured to output the first frequency band signal, the third frequency band signal, and an initial local oscillator signal in the radio frequency signals input at the input, and the second radio frequency channel is configured to output the second frequency band signal in the radio frequency signals input at the input;
the second duplexer has a third radio frequency channel and a fourth radio frequency channel both connected to the first radio frequency channel, the third radio frequency channel is configured to output the first frequency band signal, and the fourth radio frequency channel is configured to output the third frequency band signal;
the matching circuit is configured to perform impedance matching on the first dielectric filter and the second duplexer; and
the first dielectric filter is configured to filter the initial local oscillator signal to output the local oscillator signal.

The frequency selector subcircuit includes a first duplexer and a dielectric triplexer;
the first duplexer has a first radio frequency channel and a second radio frequency channel, the first radio frequency channel is configured to output the first frequency band signal, the third frequency band signal, and the local oscillator signal in the radio frequency signals input at the input, and the second radio frequency channel is configured to output the second frequency band signal in the radio frequency signals input at the input;
the dielectric triplexer has a fifth radio frequency channel, a sixth radio frequency channel, and a seventh radio frequency channel, and the fifth radio frequency channel, the sixth radio frequency channel, and the seventh radio frequency channel are all connected to the first radio frequency channel, and configured to output the first frequency band signal, the third frequency band signal, and the local oscillator signal, respectively.

The frequency selector subcircuit includes a dielectric quadplexer having an eighth radio frequency channel, a ninth radio frequency channel, a tenth radio frequency channel, and an eleventh radio frequency channel; and the eighth radio frequency channel, the ninth radio frequency channel, the tenth radio frequency channel, and the eleventh radio frequency channel are configured to select frequencies for the radio frequency signals input at the input, and output the first frequency band signal, the second frequency band signal, the third frequency band signal, and the local oscillator signal, respectively.

The mixer subcircuit includes an IQ (In-phase/Quadrature) mixer, a first matching balun, a second matching balun, a third matching balun, and a second dielectric filter;
the first matching balun is configured to perform impedance matching on the third frequency band signal and two paths of signals required by the IQ mixer;
the second matching balun is configured to perform impedance matching on the local oscillator signal and the two paths of signals required by the IQ mixer;
the third matching balun is configured to perform impedance matching on the two paths of signals output from the IQ mixer and the second dielectric filter; and
the second dielectric filter is configured to filter an initial second radio frequency signal output from the third matching balun, and output the second radio frequency signal through the second output.

The mixer subcircuit includes a non-IQ mixer and a second dielectric filter;
the non-IQ mixer is configured to mix an intermediate frequency signal with the local oscillator signal to output an initial second radio frequency signal; and
the second dielectric filter is configured to filter the initial second radio frequency signal, and output the second radio frequency signal through the second output.

The combiner subcircuit includes a duplexer.

The duplexer includes an LTCC duplexer.

In a second aspect, an embodiment of the present disclosure provides an antenna system, including any frequency conversion circuit as described above.

The antenna system further includes a first antenna unit and a second antenna unit, the first antenna unit is configured to transmit the first radio frequency signal, and the second antenna unit is configured to transmit the second radio frequency signal.

The first antenna unit includes any one of a directional antenna, an omnidirectional antenna, a horizontal antenna, an MIMO antenna, or a gain antenna.

The second antenna unit includes a directional antenna, an omnidirectional antenna, a horizontal antenna, an MIMO antenna, or a gain antenna.

The antenna system further includes a distributed antenna system.

In a third aspect, an embodiment of the present disclosure provides an electronic device, including any antenna system as described above.

### BRIEF DESCRIPTION OF DRAWINGS

FIG. 1 is a circuit diagram of a frequency conversion circuit according to an embodiment of the present disclosure.

FIG. 2 is a circuit diagram of a first example of a frequency selector subcircuit in a frequency conversion circuit according to an embodiment of the present disclosure.

FIG. 3 is a circuit diagram of a second example of a frequency selector subcircuit in a frequency conversion circuit according to an embodiment of the present disclosure.

FIG. 4 is a circuit diagram of a third example of a frequency selector subcircuit in a frequency conversion circuit according to an embodiment of the present disclosure.

FIG. 5 is a circuit diagram of a first example of a mixer subcircuit in a frequency conversion circuit according to an embodiment of the present disclosure.

FIG. 6 is a circuit diagram of a second example of a mixer subcircuit in a frequency conversion circuit according to an embodiment of the present disclosure.

### DETAIL DESCRIPTION OF EMBODIMENTS

To improve understanding of the technical solution of the present disclosure for those skilled in the art, the present disclosure will be described in detail with reference to accompanying drawings and specific implementations.

Unless otherwise defined, technical or scientific terms used in the present disclosure are intended to have general meanings as understood by those skilled in the art to which the present disclosure belongs. The words “first”, “second” and similar terms used in the present disclosure do not denote any order, quantity, or importance, but are used merely for distinguishing different components from each other. Likewise, the words “a”, “an”, or “the” and similar referents do not denote a limitation of quantity, but rather denote the presence of at least one. The word “comprise” or “include” or the like means that the element or item preceding the word contains elements or items that appear after the word or equivalents thereof, but does not exclude other elements or items. The terms “connected” or “coupled” and the like are not restricted to physical or mechanical connection, but may include electrical connection, either direct or indirect. The words “upper”, “lower”, “left”, “right”, or the like are merely used to indicate a relative positional relationship, and when an absolute position of the described object is changed, the relative positional relationship may be changed accordingly.

Before introducing the frequency conversion circuit, the antenna system, and the electronic device in the embodiments of the present disclosure, it should be noted that for the first frequency band signal, the second frequency band signal, and the third frequency band signal mentioned in the embodiments of the present disclosure, a maximum frequency of the first frequency band signal is lower than a minimum frequency of the third frequency band signal, and a maximum frequency of the third frequency band signal is lower than a minimum frequency of the second frequency band signal. For convenience of description, the first frequency band signal is referred to as a low frequency signal, the second frequency band signal is referred to as a high frequency signal, and the third frequency band signal is referred to as an intermediate frequency signal. Further, bandwidth extension of a 5G radio frequency signal, i.e., the case where the radio frequency signal in a specific frequency band is a 5G radio frequency signal, is taken as an example for illustrating the frequency conversion circuit in the embodiments of the present disclosure. However, it should be understood that for a specific application scenario, bandwidth extension of other frequency band signals can be implemented by selecting a specific device, such as a filter, in the frequency conversion circuit.

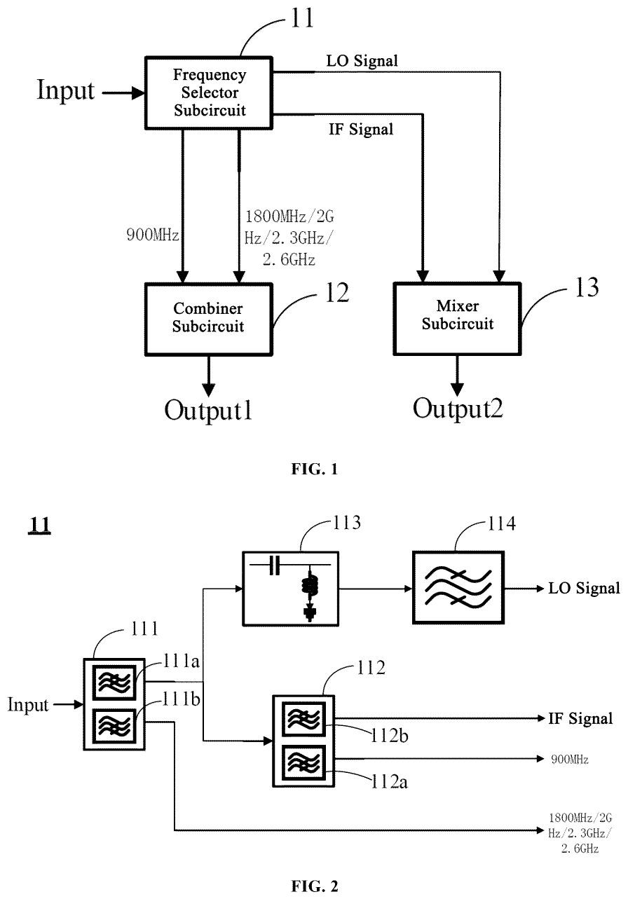

In a first aspect, FIG. 1 is a circuit diagram of a frequency conversion circuit according to an embodiment of the present disclosure. As shown in FIG. 1, an embodiment of the present disclosure provides a frequency conversion circuit having an input Input, a first output Output1, and a second output Output2. Specifically, the frequency conversion circuit includes a frequency selector subcircuit 11, a combiner subcircuit 12, and a mixer subcircuit 13. The frequency selector subcircuit 11 is configured to select, according to frequencies, a high frequency signal, a low frequency signal, an intermediate frequency signal, and a local oscillator signal from radio frequency signals input at the input Input. The combiner subcircuit 12 is configured to combine the low frequency signal and the high frequency signal, and output a first radio frequency signal including at least a 5G radio frequency signal at the first output Output1. The mixer subcircuit 13 is configured to mix the intermediate frequency signal with the local oscillator signal, and output a second radio frequency signal through the second output Output2, where the second radio frequency signal is a 5G radio frequency signal.

It should be noted that, in the embodiment of the present disclosure, the first radio frequency signal output from the first output Output1 by the combiner subcircuit 12 is composed of a high frequency signal and a low frequency signal written at the input Input. In other words, the first radio frequency signal includes a high frequency signal and a low frequency signal. It will be appreciated that the first radio frequency signal includes multiple bands of radio frequency signals, one of which is 5G radio frequency signals.

In an embodiment of the present disclosure, a frequency selector circuit is composed of only the frequency selector subcircuit 11, the combiner subcircuit 12, and the mixer subcircuit 13. Such a circuit has a simple structure, and can implement low-loss branches of signals for different purposes, so that the power loss of the entire circuit can be reduced. Moreover, the frequency selector circuit can implement bandwidth extension of 5G radio frequency signals, thereby improving the signal transmission rate and reliability.

In the following, exemplary feasible structures of the frequency selector subcircuit 11, the mixer subcircuit 13 and the combiner subcircuit 12 in the embodiments of the present disclosure are described respectively. Before describing the structures of the three parts, it should be noted that the radio frequency signals input at the input Input of the frequency conversion circuit include two parts, where the first part includes signals of a conventional communication signal frequency band (low frequency signals and high frequency signals), such as 900 MHz, 1800 MHz, 2 GHz, 2.3 GHz and 2.6 GHz signals; and the second part includes intermediate frequency signals IF and local oscillator signals LO to be converted into 2.6 GHz signals, and the IF signals and the LO signals fall in idle frequency bands of 900 MHz and 1800 MHz. The 2.6 GHz signals are 5G radio frequency signals. Accordingly, frequency bands of the first radio frequency signal output from the first output Output1 include 900 MHz, 1800 MHz, 2 GHz, 2.3 GHz and 2.6 GHz signals; and the second radio frequency signal output from the second output Output2 is another path of 2.6 GHz signals converted from IF and LO for bandwidth extension. The frequency selector subcircuit 11 is configured to split signals in the conventional communication frequency band 900 MHz, 1800 MHz, 2 GHz, 2.3 GHz, and 2.6 GHz from the IF signal and the LO signal used for frequency mixing, where the 900 MHz, 1800 MHz, 2 GHz, 2.3 GHz, and 2.6 GHz signals are directly transmitted to a coverage scene by an antenna, while the IF signals and the LO signals are mixed and then transmitted to a coverage scene via a multiplexing antenna. The mixer subcircuit 13 is mainly configured to implement the frequency conversion from IF signals to 2.6 GHz signals, so as to meet the requirements of system communication with minimum frequency conversion loss and maximum linearity. The combiner subcircuit 12 is configured to combine low frequency signals (900 MHz) and high frequency signals (1800 MHz, 2 GHz, 2.3 GHz, and 2.6 GHz signals) in non-mixed signals into one path, and output through the first output Output1. In addition, since the multiplexing operation of the frequency selector subcircuit 11 is based on the principle of splitting different signals according to frequency bands through a high-pass filter and a low-pass filter, the IF signals and the LO signals should be filtered from original signals. Therefore, the 900 MHz signals are split into a different path from the 1800 MHz, 2 GHz, 2.3 GHz and 2.6GHz signals, and at this time, the combiner subcircuit 12 combines the signals so that the antenna unit transmits the radio frequency signals for coverage.

Firstly, the frequency selector subcircuit 11 provided in the embodiments of the present disclosure is described.

First example: FIG. 2 is a circuit diagram of a first example of a frequency selector subcircuit 11 in a frequency conversion circuit according to an embodiment of the present disclosure. As shown in FIG. 2, in this example, the frequency selector subcircuit 11 is composed of two duplexers, a matching circuit 113, and a dielectric filter. For convenience of description and to distinguish from other examples, the two duplexers are referred to as a first duplexer 111 and a second duplexer 112, respectively, and the dielectric filter is referred to as a first dielectric filter 114.

The first duplexer 111 has a first radio frequency channel 111a and a second radio frequency channel 111b. The first radio frequency channel 111a is configured to output a lower frequency part of the radio frequency signals input at the input Input, i.e., output low frequency signals, intermediate frequency signals, and local oscillator signals (900 MHz signals, IF signals and LO signals). The second radio frequency channel 111b is configured to output a higher frequency part of the radio frequency signals input at the input Input, i.e., output high frequency signals (1800 MHz, 2 GHz, 2.3 GHz, and 2.6 GHz signals). The second duplexer 112 has a third radio frequency channel 112a and a fourth radio frequency channel 112b both connected to the first radio frequency channel 111a, the third radio frequency channel 112a is configured to output a low frequency signal (900 MHz), and the fourth radio frequency channel 112b is configured to output an intermediate frequency signal (IF signal). The matching circuit 113 is configured to perform impedance matching on the first dielectric filter 114 and the second duplexer 112. The first dielectric filter 114 is configured to filter the initial local oscillator signal to output a local oscillator signal (LO signal).

It should be noted that the first radio frequency channel 111a, the second radio frequency channel 111b, the third radio frequency channel 112a, and the fourth radio frequency channel 112b can output radio frequency signals in the specific frequency band because these channels are configured with corresponding filters, such as a low-pass filter, a high-pass filter, or the like.

In this example, the LO signal is filtered by the first dielectric filter 114 because the LO signal has a frequency closer to a low frequency signal (900 MHz) and the IF signal, so that filtering with the first dielectric filter 114 can achieve greater out-of-band rejection, thereby avoid increasing the insertion loss of other radio frequency channels.

In some examples, the first duplexer 111 and the second duplexer 112 include, but are not limited to, low temperature co-fired ceramic (LTCC) duplexers.

In some examples, the first dielectric filter 114 in the embodiment includes, but is not limited to, an LTCC filter.

In some examples, the matching circuit 113 may be formed by a capacitor, an inductor, and the like electrically connected.

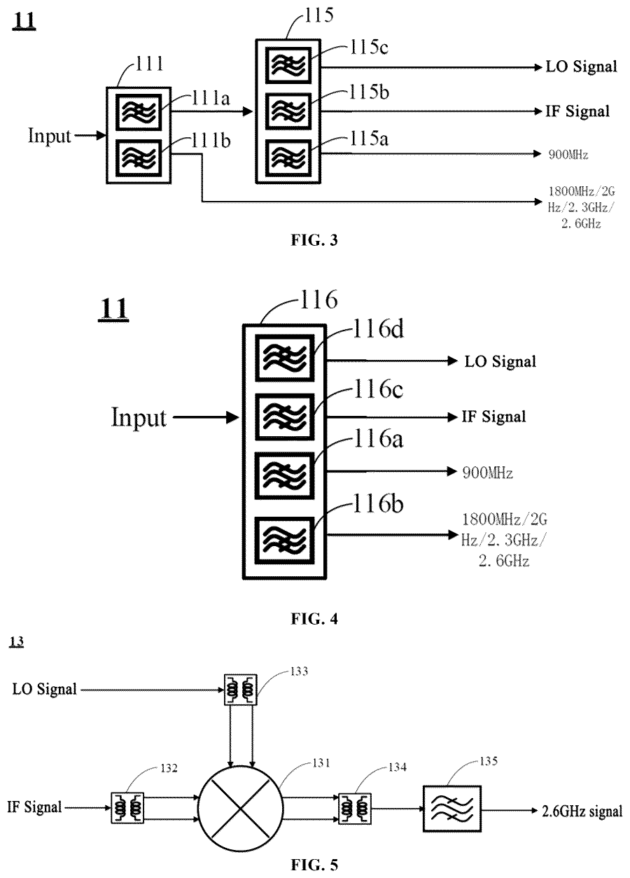

Second example: FIG. 3 is a circuit diagram of a second example of a frequency selector subcircuit 11 in a frequency conversion circuit according to an embodiment of the present disclosure. As shown in FIG. 3, in this example, the frequency selector subcircuit 11 includes a duplexer and a dielectric triplexer 115. Since this duplexer has the same function as the first duplexer 111 in the first example, this duplexer is also referred to as a first duplexer 111.

The first duplexer 111 has a first radio frequency channel 111a and a second radio frequency channel 111b. The first radio frequency channel 111a is configured to output a lower frequency part of the radio frequency signals input at the input Input, i.e., output low frequency signals, intermediate frequency signals, and local oscillator signals (900 MHz signals, IF signals and LO signals). The second radio frequency channel 111b is configured to output a higher frequency part of the radio frequency signals input at the input Input, i.e., output high frequency signals (1800 MHz, 2 GHz, 2.3 GHz, and 2.6 GHz signals). The dielectric triplexer 115 has a fifth radio frequency channel 115a, a sixth radio frequency channel 115b, and a seventh radio frequency channel 115c each connected to the first radio frequency channel 111a. The fifth radio frequency channel 115a is configured to output a low frequency signal (900 MHz), the sixth radio frequency channel 115b is configured to output an IF signal; and the seventh radio frequency channel 115c is configured to output an LO signal.

It should be noted that the first radio frequency channel 111a, the second radio frequency channel 111b, the fifth radio frequency channel 115a, the sixth radio frequency channel 115b, and the seventh radio frequency channel 115c can output radio frequency signals in the specific frequency band because these channels are configured with corresponding filters, such as a low-pass filter, a high-pass filter, or the like.

In this example, the dielectric triplexer 115 is used to split the low frequency signal (900 MHz), the IF signal, and the LO signal into three paths. Since the three frequency bands are close to each other, the use of the out-of-band rejection dielectric triplexer 115 can greatly reduce the insertion loss of the IF signal, thereby reducing the frequency conversion loss of the entire system.

In some examples, the first duplexer 111 includes, but is not limited to, an LTCC duplexer.

Third example: FIG. 4 is a circuit diagram of a third example of a frequency selector subcircuit 11 in a frequency conversion circuit according to an embodiment of the present disclosure. As shown in FIG. 4, in this example, the frequency selector subcircuit 11 includes a dielectric quadplexer 116 having an eighth radio frequency channel 116a, a ninth radio frequency channel 116b, a tenth radio frequency channel 116c, and an eleventh radio frequency channel 116d. The eighth radio frequency channel 116a is configured to perform frequency selection on the radio frequency signals input at the input Input to output a low frequency signal; the ninth radio frequency channel 116b is configured to perform frequency selection on the radio frequency signals input at the input Input to output a high frequency signal; the tenth radio frequency channel 116c is configured to perform frequency selection on the radio frequency signals input at the input Input to output an IF signal; and the eleventh radio frequency channel 116d is configured to perform frequency selection on the radio frequency signals input at the input Input to output an LO signal.

In this example, the frequency selector subcircuit 11 uses a dielectric quadplexer 116 configured to split the radio frequency signals input at the input Input into four paths. In this case, the integration level of the circuits can be further enhanced, and the complexity of the circuits is reduced, thereby facilitating production.

Next, the mixer subcircuit 13 provided in the embodiments of the present disclosure will be described.

First example: FIG. 5 is a circuit diagram of a first example of a mixer subcircuit 13 in a frequency conversion circuit according to an embodiment of the present disclosure. As shown in FIG. 5, in this example, the mixer subcircuit 13 is composed of an IQ mixer 131, three matching baluns, and a dielectric filter. For convenience of description and to distinguish from other examples, the three matching baluns are referred to as a first matching balun 132, a second matching balun 133, and a third matching balun 134, respectively, and the dielectric filter is referred to as a second dielectric filter 135.

The IQ mixer 131 is a double-balanced IQ mixer 131 configured to receive and output a differential signal. Therefore, the first matching balun 132 is configured to perform impedance matching on the IF signal and two paths of differential signals required by the IQ mixer 131; the second matching balun 133 is configured to perform impedance matching on the LO signal and two paths of signals required by the IQ mixer 131; and the third matching balun 134 is configured to perform impedance matching on the two paths of signals output from the IQ mixer 131 and the second dielectric filter 135. The second dielectric filter 135 is configured to filter an initial second radio frequency signal output from the third matching balun 134, and output a 5G radio frequency signal of 2.6 GHz through the second output Output2.

In this example, a double-balanced IQ mixer 131 is used for frequency conversion of the IF and LO signals to generate another path of 2.6 GHz signal, which can achieve an optimal combination of isolation, linearity, and noise figure, while enhancing image rejection and ensuring non-linear performance of the system. Meanwhile, the second dielectric filter 135 is configured to filter a 2.6 GHz band signal generated by the frequency conversion, and remove out-of-band spurious signals generated by frequency mixing, thereby ensuring the communication quality.

In some examples, the second dielectric filter 135 in the embodiment includes, but is not limited to, an LTCC filter.

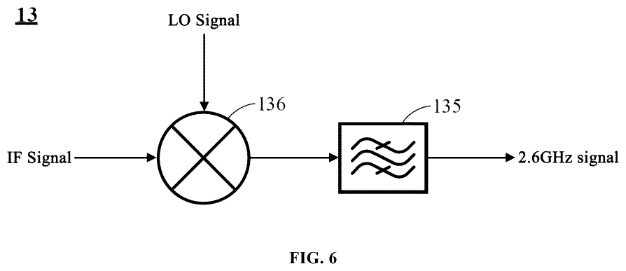

Second example: FIG. 6 is a circuit diagram of a second example of a mixer subcircuit 13 in a frequency conversion circuit according to an embodiment of the present disclosure. As shown in FIG. 6, in this example, the mixer subcircuit 13 includes a non-IQ mixer 136 and a dielectric filter. This dielectric filter has the same function as the dielectric filter in the mixer subcircuit 13 of the first example described above, and thus is also referred to as a second dielectric filter 135.

The non-IQ mixer 136 is configured to mix an intermediate frequency signal with the local oscillator signal to output an initial second radio frequency signal; and the second dielectric filter 135 is configured to filter the initial second radio frequency signal, and output a 5G radio frequency signal of 2.6 GHz through the second output Output2.

In this example, compared with the mixer subcircuit 13 in the first example, the non-IQ mixer 136 can eliminate the need for matching baluns, and since the matching baluns tends to cause mismatch of different degrees and increase loss due to various reasons in actual wiring, replacing the IQ mixer 131 with the non-IQ mixer 136 can reduce the conversion loss to some extent. Meanwhile, the second dielectric filter 135 is configured to filter a 2.6 GHz band signal generated by the frequency conversion, and remove out-of-band spurious signals generated by frequency mixing, thereby ensuring the communication quality.

In some examples, the second dielectric filter 135 in the embodiment includes, but is not limited to, an LTCC filter.

Finally, the combiner subcircuit 12 provided in the embodiments of the present disclosure will be described. The combiner subcircuit 12 in the embodiment of the present disclosure adopts a duplexer, which may be specifically an LTCC duplexer. Signals are reversely combined by the duplexer so that the antenna unit transmits the radio frequency signals for coverage.

In a second aspect, an embodiment of the present disclosure provides an antenna system, including any frequency conversion circuit as described above, through which a signal source of the antenna system is provided. The antenna system in the embodiment of the present disclosure may be specifically a distributed antenna system (DAS).

In some examples, in addition to the signal source, the antenna system further includes a transmission medium and an antenna unit. The signal source is connected to the antenna unit via the transmission medium. In an embodiment of the present disclosure, the antenna unit may specifically include a first antenna unit and a second antenna unit. The first antenna unit is configured to transmit the first radio frequency signal, and the second antenna unit is configured to transmit the second radio frequency signal.

Further, the transmission medium may be a coaxial cable, an optical cable, an LAN, or the like.

In some examples, the antenna system in the embodiment of the present disclosure is a passive DAS which is mainly applied to small buildings and spaces. Only a coaxial cable is used to deliver a radio frequency signal from a base station or repeater to the antenna unit. The electronic components used include: a separator, a combiner, an attenuator, a dummy load, a circulator, a filter, and a coupler.

In some examples, the antenna system may include a transceiver antenna which can transmit and receive electromagnetic wave signals. Apparently, the antenna system is not limited to the above structures, and may further include a transceiver unit, a radio frequency transceiver, a signal amplifier, a power amplifier, and a filter unit. The antenna may be used as a transmitting antenna or a receiving antenna in a communication device. The transceiver unit may include a baseband and a receiving end. The baseband provides signals of at least one frequency band, for example, 2G signals, 3G signals, 4G signals, 5G signals, or the like, and transmits the signals of the at least one frequency band to the radio frequency transceiver. After being received by the antenna in the communication system, the signals may be processed by the filter unit, the power amplifier, the signal amplifier, and the radio frequency transceiver, and then transmitted to the receiving end in the transceiver unit. The receiving end may be, for example, an intelligent gateway, or the like.

Further, the radio frequency transceiver is connected to the transceiver unit, and configured to modulate a signal sent from the transceiver unit, or demodulate a signal received by the antenna and transmit the demodulated signal to the transceiver unit. Specifically, the radio frequency transceiver may include a transmitting circuit, a receiving circuit, a modulation circuit, and a demodulation circuit. After being received by the transmitting circuit, multiple types of signals provided by the baseband can be modulated by the modulation circuit and then transmitted to the antenna. Then, the antenna receives and transmits the signals to the receiving circuit of the radio frequency transceiver which further transmits the signals to the demodulation circuit, where the signals are demodulated by the demodulation circuit and then transmitted to the receiving end.

Further, the radio frequency transceiver is connected to the signal amplifier and the power amplifier which are further connected to the filter unit, and the filter unit is connected to at least one antenna. In the process of transmitting signals by a communication system, the signal amplifier is configured to increase a signal-to-noise ratio of a signal output from the radio frequency transceiver, and then transmit the signal to the filter unit. The power amplifier is configured to amplify a power of the signal output from the radio frequency transceiver and then transmit the signal to the filter unit. The filter unit may specifically include a duplexer and a filter circuit. The filter unit combines the signals output from the signal amplifier and the power amplifier, filters noise waves, and then transmits the signals to the antenna to be radiated. In the process of receiving signals by a communication system, after being received by the antenna, the signals are transmitted to the filter unit, where the signals received by the antenna are filtered to remove noise waves by the filter unit and then transmitted to the signal amplifier and the power amplifier. The signal amplifier increases a gain of the signals received by the antenna to increase a signal-to-noise ratio of the signals; while the power amplifier amplifies a power of the signals received by the antenna. After being processed by the power amplifier and the signal amplifier, the signals received by the antenna are transmitted to the radio frequency transceiver, and then to the transceiver unit.

In some examples, the signal amplifier may include various types of signal amplifiers, such as a low noise amplifier, which is not limited herein.

In some examples, the antenna system provided in the embodiments of the present disclosure further includes a power management unit, which is connected to the power amplifier and provides a voltage for signal amplification for the power amplifier.

In a third aspect, an embodiment of the present disclosure provides an electronic device, including the antenna system as described above.

It will be appreciated that the above implementations are merely exemplary implementations for the purpose of illustrating the principle of the present disclosure, and the present disclosure is not limited thereto. Various modifications and improvements can be made by those skilled in the art without departing from the spirit and essence of the present disclosure. Accordingly, all of the modifications and improvements also fall into the protection scope of the present disclosure.

1. A frequency conversion circuit, having an input, a first output, and a second output; wherein the frequency conversion circuit comprises a frequency selector subcircuit, a combiner subcircuit, and a mixer subcircuit; wherein
the frequency selector subcircuit is configured to select, according to frequencies, a first frequency band signal, a second frequency band signal, a third frequency band signal, and a local oscillator signal from radio frequency signals input at the input; and the third frequency band signal has a frequency between frequencies of the first frequency band signal and the second frequency band signal;
the combiner subcircuit is configured to combine the first frequency band signal and the second frequency band signal, and output, at the first output, a first radio frequency signal comprising at least a radio frequency signal in a specific frequency band; and
the mixer subcircuit is configured to mix the third frequency band signal with the local oscillator signal, and output a second radio frequency signal through the second output, wherein the second radio frequency signal is the radio frequency signal in the specific frequency band.

2. The frequency conversion circuit according to claim 1, wherein the radio frequency signal in the specific frequency band is a 5G radio frequency signal.

3. The frequency conversion circuit according to claim 1, wherein the frequency selector subcircuit comprises a first duplexer, a second duplexer, a matching circuit, and a first dielectric filter;
the first duplexer has a first radio frequency channel and a second radio frequency channel, the first radio frequency channel is configured to output the first frequency band signal, the third frequency band signal, and an initial local oscillator signal in the radio frequency signals input at the input, and the second radio frequency channel is configured to output the second frequency band signal in the radio frequency signals input at the input;
the second duplexer has a third radio frequency channel and a fourth radio frequency channel both connected to the first radio frequency channel, the third radio frequency channel is configured to output the first frequency band signal, and the fourth radio frequency channel is configured to output the third frequency band signal;
the matching circuit is configured to perform impedance matching on the first dielectric filter and the second duplexer; and
the first dielectric filter is configured to filter the initial local oscillator signal to output the local oscillator signal.

4. The frequency conversion circuit according to claim 1, wherein the frequency selector subcircuit comprises a first duplexer and a dielectric triplexer;
the first duplexer has a first radio frequency channel and a second radio frequency channel, the first radio frequency channel is configured to output the first frequency band signal, the third frequency band signal, and the local oscillator signal in the radio frequency signals input at the input, and the second radio frequency channel is configured to output the second frequency band signal in the radio frequency signals input at the input; and
the dielectric triplexer has a fifth radio frequency channel, a sixth radio frequency channel, and a seventh radio frequency channel, and the fifth radio frequency channel, the sixth radio frequency channel, and the seventh radio frequency channel are all connected to the first radio frequency channel, and configured to output the first frequency band signal, the third frequency band signal, and the local oscillator signal, respectively.

5. The frequency conversion circuit according to claim 1, wherein the frequency selector subcircuit comprises a dielectric quadplexer having an eighth radio frequency channel, a ninth radio frequency channel, a tenth radio frequency channel, and an eleventh radio frequency channel; and the eighth radio frequency channel, the ninth radio frequency channel, the tenth radio frequency channel, and the eleventh radio frequency channel are configured to select frequencies for the radio frequency signals input at the input, and output the first frequency band signal, the second frequency band signal, the third frequency band signal, and the local oscillator signal, respectively.

6. The frequency conversion circuit according to claim 1, wherein the mixer subcircuit comprises an IQ mixer, a first matching balun, a second matching balun, a third matching balun, and a second dielectric filter;
the first matching balun is configured to perform impedance matching on the third frequency band signal and two paths of signals required by the IQ mixer;
the second matching balun is configured to perform impedance matching on the local oscillator signal and the two paths of signals required by the IQ mixer;
the third matching balun is configured to perform impedance matching on the two paths of signals output from the IQ mixer and the second dielectric filter; and
the second dielectric filter is configured to filter an initial second radio frequency signal output from the third matching balun, and output the second radio frequency signal through the second output.

7. The frequency conversion circuit according to claim 1, wherein the mixer subcircuit comprises a non-IQ mixer and a second dielectric filter;
the non-IQ mixer is configured to mix an intermediate frequency signal with the local oscillator signal to output an initial second radio frequency signal; and
the second dielectric filter is configured to filter the initial second radio frequency signal, and output the second radio frequency signal through the second output.

8. The frequency conversion circuit according to claim 1, wherein the combiner subcircuit comprises a duplexer.

9. The frequency conversion circuit according to claim 8, wherein the duplexer comprises an LTCC duplexer.

10. An antenna system, comprising the frequency conversion circuit according to claim 1.

11. The antenna system according to claim 10, further comprising a first antenna unit and a second antenna unit, the first antenna unit is configured to transmit the first radio frequency signal, and the second antenna unit is configured to transmit the second radio frequency signal.

12. The antenna system according to claim 11, wherein the first antenna unit comprises any one of a directional antenna, an omnidirectional antenna, a horizontal antenna, an MIMO antenna, or a gain antenna.

13. The antenna system according to claim 11, wherein the second antenna unit comprises a directional antenna, an omnidirectional antenna, a horizontal antenna, an MIMO antenna, or a gain antenna.

14. The antenna system according to claim 10, wherein the antenna system comprises a distributed antenna system.

15. An electronic device, comprising the antenna system according to claim 10.
